(19) United States
(12) Patent Application Publication
(10) Pub. No.: US 2017/0173634 A1
(43) Pub. Date: Jun. 22, 2017

(54) STRETCHABLE FILM LAMINATE AND ELECTRONIC DEVICE

(71) Applicant: Murata Manufacturing Co., Ltd., Nagaokakyo-shi (JP)

(72) Inventors: Junichi Hashimoto, Nagaokakyo-shi (JP); Masamichi Ando, Nagaokakyo-shi (JP)

(21) Appl. No.: 15/451,847

(22) Filed: Mar. 7, 2017

Related U.S. Application Data
(63) Continuation of application No. PCT/JP2015/073950, filed on Aug. 26, 2015.

(30) Foreign Application Priority Data
Sep. 12, 2014 (JP) 2014-186376

(51) Int. Cl. B06B 1/06; H01L 41/04; H01L 41/047; H01L 41/113; H01L 41/193; H01L 41/338; H04R 17/00; H04R 7/04; H01L 41/09; H01L 41/083

(52) U.S. Cl. CPC B06B 1/06; H01L 41/09; H01L 41/042; H01L 41/0471; H01L 41/0472; H01L 41/083; H01L 41/193; H01L 41/338; H04R 17/00; H04R 7/04; H01L 41/1132

(57) ABSTRACT

A stretchable film laminate that includes a laminated body and external electrodes. The laminated body is formed such that a plurality of stretchable films and a plurality of main-surface electrodes are laminated in an alternate manner. The stretchable films are provided with cuts through which some of the main-surface electrodes are partially exposed. The external electrodes are connected to a part of the main-surface electrodes exposed through the cuts.

### CROSS REFERENCE TO RELATED APPLICATIONS

The present application is a continuation of International application No. PCT/JP2015/073950, filed Aug. 26, 2015, which claims priority to Japanese Patent Application No. 2014-186376, filed Sep. 12, 2014, the entire contents of each of which are incorporated herein by reference.

### FIELD OF THE INVENTION

The present invention relates to a stretchable film laminate obtained by laminating stretchable films that stretch in a planar direction through the application of a voltage, and an electronic device including the stretchable film laminate.

### BACKGROUND OF THE INVENTION

Conventionally, many stretchable film laminates have been used which are obtained by laminating stretchable films that stretch in a planar direction through the application of a voltage. For example, Patent Document 1 discloses a piezoelectric speaker 90 as shown in FIG. 10.

FIG. 10 is a cross-sectional view of the piezoelectric speaker 90 according to Patent Document 1.

The piezoelectric speaker 90 includes a laminated body 2, a positive electrode 9 (first external electrode), a negative electrode 10 (second external electrode), and a diaphragm 11.

The laminated body 2 is a cuboid. The laminated body 2 is formed such that first main-surface electrodes 5, film layers 1 (piezoelectric films), and second main-surface electrodes 6 are laminated in an alternate manner. The film layers 1 are composed of a polylactic acid. The positive electrode 9 for the application of driving signals, which is connected to the plurality of first main-surface electrodes 5, is provided on one end surface of the laminated body 2.

In addition, the negative electrode 10 for the application of driving signals, which is connected to the plurality of second main-surface electrodes 6, is provided on the other end surface of the laminated body 2. The laminated body 2 is bonded to one principal surface of the diaphragm 11 with an adhesive layer 12 interposed therebetween.

In the foregoing configuration, when a driving voltage (driving signal) is applied to the laminated body 2 from the plurality of first main-surface electrodes 5 and the plurality of second main-surface electrodes 6 through the positive electrode 9 and the negative electrode 10, the laminated body 2 stretches, for example, in a planar direction perpendicular to the laminating direction, thereby vibrating the diaphragm 11. Thus, the piezoelectric speaker 90 emits a sound.

Patent Document 1: Japanese Patent Application Laid-Open No. 2014-68141

### SUMMARY OF THE INVENTION

However, the piezoelectric speaker 90 in Patent Document 1 has a narrow connection area between the first main-surface electrodes 5 and the positive electrode 9. Likewise, the speaker has a narrow connection area between the second main-surface electrodes 6 and the negative electrode 10.

Therefore, in the piezoelectric speaker 90 in Patent Document 1, the connection strength is low between the first main-surface electrodes 5 and the positive electrode 9 (first external electrode), and there is a possibility of causing defective bonding such as peeling between the first main-surface electrodes 5 and the positive electrode 9. Likewise, the connection strength is low between the second main-surface electrodes 6 and the negative electrode 10 (second external electrode), and there is a possibility of causing defective bonding such as peeling between the second main-surface electrodes 6 and the negative electrode 10.

Further, because of the narrow connection area between the first main-surface electrodes 5 and the positive electrode 9, long-term heating is required so as to ensure that both electrodes are reliably connected to each other. However, there is a possibility that the film layers 1 will be melted during this heating.

Therefore, an object of the present invention is to provide a stretchable film laminate and an electronic device which can improve the connection strength between a main-surface electrode and an external electrode.

A stretchable film laminate according to the present invention includes a laminated body formed by laminating: a first main-surface electrode; a first stretchable film with a first main surface bonded to the first main-surface electrode and a second main surface opposed to the first main surface; a second main-surface electrode bonded to the second main surface of the first stretchable film; a second stretchable film with a third main surface bonded to the second main-surface electrode and a fourth main surface opposed to the third main surface; and a third main-surface electrode bonded to the fourth main surface of the second stretchable film.

The first stretchable film and the second stretchable film are provided with a first cut through which the third main-surface electrode is partially exposed.

Further, the stretchable film laminate according to the present invention includes a first external electrode connected to a part of the main surface of the first main-surface electrode and a part of the main surface of the third main-surface electrode exposed through the first cut.

In accordance with this configuration, the first external electrode can be connected to the first and third main-surface electrodes on the main-surface side where a large area can be ensured. Accordingly, the connection area between the first external electrode and the first and third main-surface electrodes is larger than the connection area of the piezoelectric speaker 90 in Patent Document 1.

Therefore, the stretchable film laminate in accordance with this configuration can improve the connection strength between the first external electrode and the first and third main-surface electrodes.

In addition, according to the present invention, the laminated body may be, in one aspect, formed by further laminating: a third stretchable film with a fifth main surface bonded to the third main-surface electrode and a sixth main surface opposed to the fifth main surface; and a fourth main-surface electrode bonded to the sixth main surface of the third stretchable film.

Further, the second stretchable film and the third stretchable film are preferably provided with a second cut through which the second main-surface electrode is partially exposed. A second external electrode is connected to a part of the main surface of the fourth main-surface electrode and a part of the main surface of the second main-surface electrode exposed through the second cut.

In accordance with this configuration, the second external electrode can be connected to the second and fourth main-surface electrodes on the main-surface side where a large area can be ensured. Accordingly, in accordance with this configuration, the connection area between the second external electrode and the second and fourth main-surface electrodes is larger than the connection area of the piezoelectric speaker 90 in Patent Document 1.

Therefore, the stretchable film laminate in accordance with this configuration can further improve the connection strength between the second external electrode and the second and fourth main-surface electrodes.

It is to be noted that in the foregoing configuration, when a driving voltage (driving signal) is applied to the laminated body through the first and second external electrodes from the first and third main-surface electrodes and the second and fourth main-surface electrodes, the laminated body stretches, for example, in the laminating direction.

In addition, the first external electrode or the second external electrode may be, in one aspect, stepped.

In addition, when the first cut or the second cut has a corner, the stretchable films are likely to be ruptured from the corner part in the stretching direction of the stretchable films, e.g., in the formation of the first cut or the second cut by punching of the stretchable films with a press mold. Therefore, the first cut or the second cut is preferably curved.

In accordance with this configuration, the first cut or the second cut has no corner, and can be thus prevented from being ruptured.

In addition, the stretchable films desirably have an electrostrictive material that stretches in a direction parallel to the main surfaces when an electric field is applied in a direction normal to the main surfaces, in particular, a (vinylidene fluoride-ethylene trifluoride-chloroethene trifluoride) terpolymer P(VDF/TrFE/CTFE) or a vinylidene fluoride-ethylene trifluoride copolymer P(VDF/TrFE) with a high electrostrictive coefficient. In addition, a polyvinylidene fluoride that stretches even in a low electric field can be also adopted as a material, and a chiral polymer can be used as a material. In particular, when a chiral polymer is a polylactic acid, the adoption of a light-transmitting material for the films, and also for the other configurations, can achieve a stretchable film laminate that has a highly light-transmitting property substantially over the entire surface in a frontal view. The polylactic acid is preferably an L-type polylactic acid.

In addition, an electronic device can be configured to include the stretchable film laminate according to the present invention. Therefore, the electronic device according to the present invention achieves similar benefits to that of the stretchable film laminate according to the present invention.

According to this invention, the connection strength can be improved between the main-surface electrodes and the external electrodes.

### BRIEF EXPLANATION OF THE DRAWINGS

FIG. 1 is a perspective view of the appearance of a stretchable film laminate 100 according to a first embodiment of the present invention.

FIG. 2 is a perspective view of the appearance of the stretchable film laminate 100 shown in FIG. 1.

FIG. 3 is a perspective view of the appearance of a laminated body 102 shown in FIG. 1.

FIG. 4 is a perspective view of the appearance of the laminated body 102 shown in FIG. 1.

FIG. 5 is a front view of the laminated body 102 shown in FIG. 1.

FIG. 6 is a perspective view of the appearance of a stretchable film laminate 200 according to a second embodiment of the present invention.

FIG. 7 is a cross-sectional view of a main part of a stretchable film laminate 300 according to a third embodiment of the present invention.

FIG. 8 is a perspective view of an interlayer connection part of a stretchable film laminate 400 according to a fourth embodiment of the present invention.

FIG. 9 is a perspective view of the appearance of a keyboard 800 according to another embodiment of the present invention.

FIG. 10 is a cross-sectional view of a piezoelectric speaker 90 according to Patent Document 1.

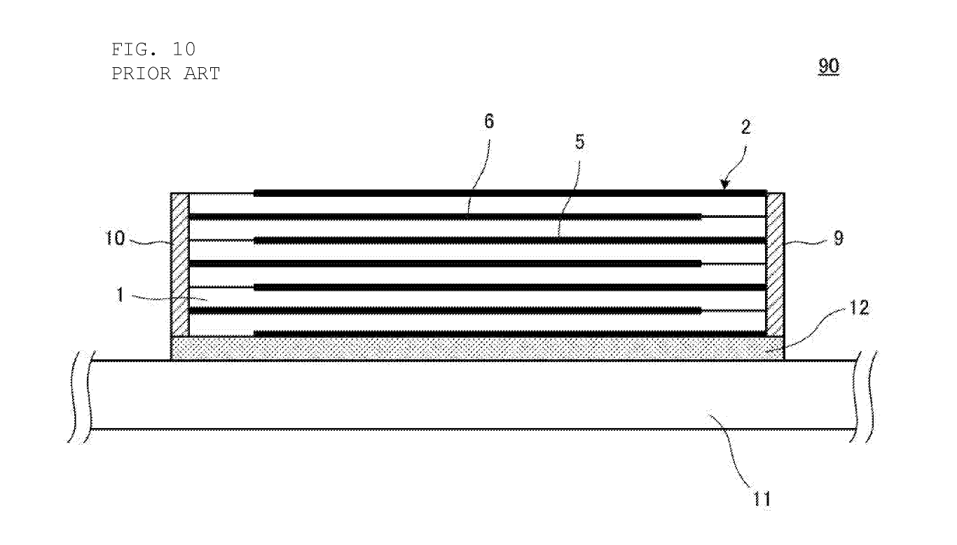

### DETAILED DESCRIPTION OF THE INVENTION

A stretchable film laminate according to a first embodiment of the present invention will be described with reference to the drawings.

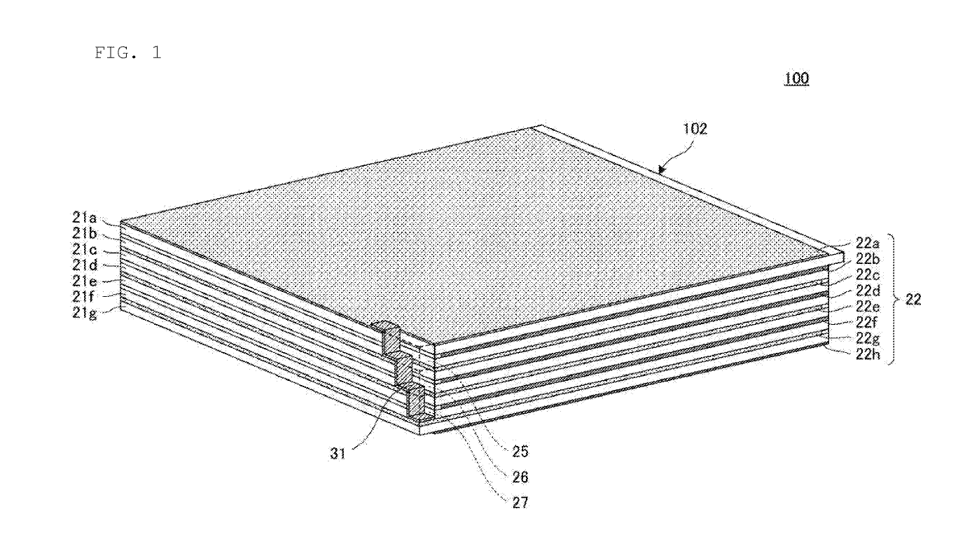

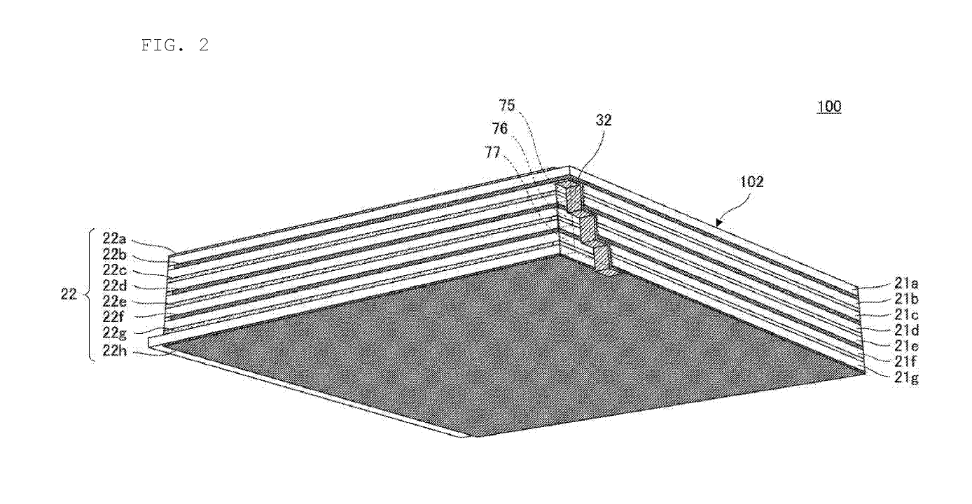

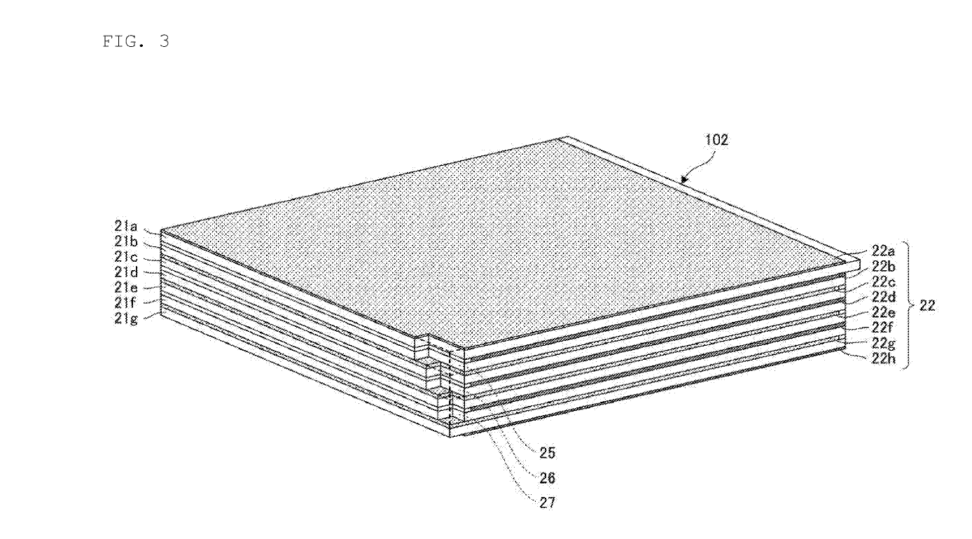

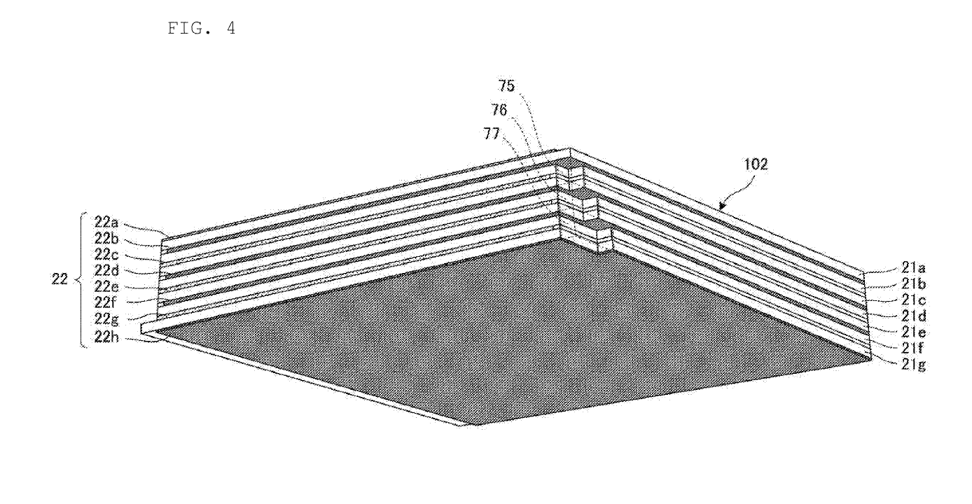

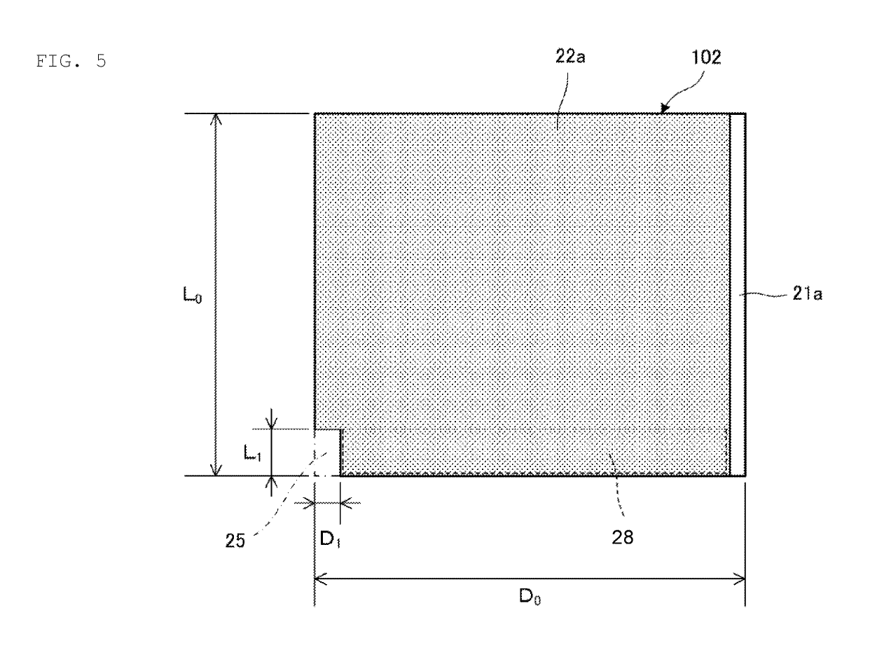

FIG. 1 is a perspective view of the appearance of a stretchable film laminate 100 according to the first embodiment of the present invention. FIG. 2 is a perspective view of the appearance of the stretchable film laminate 100 shown in FIG. 1. FIG. 3 is a perspective view of the appearance of a laminated body 102 shown in FIG. 1. FIG. 4 is a perspective view of the appearance of the laminated body 102 shown in FIG. 1. FIG. 5 is a front view of the laminated body 102 shown in FIG. 1.

It is to be noted that FIG. 1 is a view of the stretchable film laminate 100 from a main-surface electrode 22a (near side), whereas FIG. 2 is a view of the stretchable film laminate 100 from a main-surface electrode 22h (far side). FIG. 3 is a view of the stretchable film laminate 100 with an external electrode 31 removed therefrom, whereas FIG. 4 is a view of the stretchable film laminate 100 with an external electrode 32 removed therefrom.

The stretchable film laminate 100 includes the laminated body 102, the external electrode 31, and the external electrode 32.

It is to be noted that the external electrode 31 corresponds to the first external electrode. Further, the external electrode 32 corresponds to the second external electrode.

The laminated body 102 is short in the laminating direction, and has the shape of a cuboid. The laminated body 102 is formed such that a plurality of stretchable films 21a to 21g and a plurality of main-surface electrodes 22a to 22h are laminated in an alternate manner.

The stretchable films 21a to 21g each stretch in a planar direction, for example, through the application of a voltage. For the stretchable films 21a to 21g, a (vinylidene fluoride-ethylene trifluoride-chloroethene trifluoride) terpolymer P(VDF/TrFE/CTFE) or a vinylidene fluoride-ethylene trifluoride copolymer P(VDF/TrFE) is used as an electrostrictive material. In addition, a piezoelectric resin material may be used such as polyvinylidene fluoride (PVDF) and chiral polymers. The films composed of a highly light-transmitting polylactic acid (PLA), in particular, an L-type polylactic acid (PLLA), and the other configurations also made with the use of highly light-transmitting materials can achieve the stretchable film laminate 100 which has a highly light-transmitting property substantially over the entire surface in a frontal view.

When the stretchable films 21a to 21g are each composed of a PLLA, cutting the films such that each peripheral side makes substantially 45° with respect to the extending direction forms rectangular shapes with piezoelectricity. In this regard, the term of substantially 45° represents 45°±10°.

It is to be noted that the PLLA without pyroelectricity is not affected by the change in ambient temperature. Therefore, the vibration strength is not changed by the change in temperature, heat generation of an electronic device, temperature change by contact with a finger, or the like.

The external electrodes 31, 32 are stepped as shown in FIGS. 1 and 2. Leads, not shown, are bonded with a solder respectively to the external electrodes 31, 32. The external electrodes 31, 32 are provided for stretching the stretchable film laminate 100, for example, in the laminating direction through the application of a driving voltage to the stretchable film 21 through the main-surface electrode 22. The external electrodes 31, 32 are formed from Ag, Cu, Au, Cr, Ni, Al, or an alloy or the like of these metals.

In addition, the main-surface electrode 22 of the laminated body 102 is composed of the plurality of main-surface electrodes 22a to 22h.

The main-surface electrodes 22a, 22c, 22e, 22g each have one end connected to the external electrode 31. The main-surface electrodes 22a, 22c, 22e, 22g extend horizontally (in a direction perpendicular to the laminating direction) from the external electrode 31 toward the external electrode 32.

In this regard, the widthwise length of the laminated body 102 at the main-surface electrodes 22a, 22c, 22e, 22g is shorter than the length from a side surface of the laminated body 102 closer to the external electrode 32, to the external electrode 31. Therefore, the main-surface electrodes 22a, 22c, 22e, 22g are not connected to the external electrode 32.

It is to be noted that the main-surface electrode 22a corresponds to the first main-surface electrode. The main-surface electrodes 22c, 22e correspond to the first main-surface electrode or the third main-surface electrode. The main-surface electrode 22g corresponds to the third main-surface electrode.

The main-surface electrodes 22b, 22d, 22f are located between the main-surface electrodes 22a and 22c, between the main-surface electrodes 22c and 22e, and between the main-surface electrodes 22e and 22g, respectively. The main-surface electrodes 22b, 22d, 22f, 22h each have one end connected to the external electrode 32. The main-surface electrodes 22b, 22d, 22f, 22h extend horizontally (in a direction perpendicular to the laminating direction) from the external electrode 32 toward the external electrode 31.

In this regard, the widthwise length of the laminated body 102 at the main-surface electrodes 22b, 22d, 22f, 22h is shorter than the length from a side surface of the laminated body 102 closer to the external electrode 31, to the external electrode 32. Therefore, the main-surface electrodes 22b, 22d, 22f, 22h are not connected to the external electrode 31.

It is to be noted that the main-surface electrode 22b corresponds to the second main-surface electrode. The main-surface electrodes 22d, 22f correspond to the second main-surface electrode or the fourth main-surface electrode. The main-surface electrode 22h corresponds to the fourth main-surface electrode.

The main-surface electrode 22 is formed from, for example, Ag, Cu, Au, Cr, Ni, Al, or an alloy or the like of these metals.

In this regard, as shown in FIG. 3, the stretchable films 21a, 21b are provided with a cut 25 through which the main-surface electrode 22c is partially exposed. The stretchable films 21c, 21d are provided with a cut 26 through which the main-surface electrode 22e is partially exposed.

In addition, the stretchable films 21e, 21f are provided with a cut 27 through which the main-surface electrode 22g is partially exposed.

It is to be noted to the cuts 25 to 27 correspond to the first cut according to the present invention.

In addition, as shown in FIG. 4, the stretchable films 21g, 21f are provided with a cut 77 through which the main-surface electrode 22f is partially exposed. The stretchable films 21e, 21d are provided with a cut 76 through which the main-surface electrode 22d is partially exposed.

The stretchable films 21c, 21b are provided with a cut 75 through which the main-surface electrode 22b is partially exposed.

It is to be noted that the cuts 75 to 77 correspond to the second cut according to the present invention.

Further, as shown in FIG. 1, the external electrode 31 is connected to a part of the main surface of the main-surface electrode 22a and parts of the main surfaces of the main-surface electrodes 22c, 22e, 22g exposed through the cuts 25 to 27. In addition, as shown in FIG. 2, the external electrode 32 is connected to a part of the main surface of the main-surface electrode 22h and parts of the main surfaces of the main-surface electrodes 22f, 22d, 22b exposed through the cuts 75 to 77.

Therefore, in the stretchable film laminate 100, the external electrode 31 can be connected to the main-surface electrodes 22a, 22c, 22e, 22g on the main-surface side where a large area can be ensured. Accordingly, the connection area between the external electrode 31 and the main-surface electrodes 22a, 22c, 22e, 22g is larger than the connection area of the piezoelectric speaker 90 in Patent Document 1.

Likewise, in the stretchable film laminate 100, the external electrode 32 can be connected to the main-surface electrodes 22h, 22f, 22d, 22b on the main-surface side where a large area can be ensured. Therefore, the connection area between the external electrode 32 and the main-surface electrodes 22h, 22f, 22d, 22b is larger than the connection area of the piezoelectric speaker 90 in Patent Document 1.

Therefore, the stretchable film laminate 100 can improve the connection strength between the external electrode 31 and the main-surface electrodes 22a, 22c, 22e, 22g. Furthermore, the stretchable film laminate 100 can improve the connection strength between the external electrode 32 and the main-surface electrodes 22h, 22f, 22d, 22b.

In accordance with the foregoing configuration, when an alternating-current driving voltage (driving signal) is applied from the leads bonded to the external electrodes 31, 32, the driving voltage is applied to the laminated body 102 from the main-surface electrodes 22a, 22c, 22e, 22g and the main-surface electrodes 22b, 22d, 22f, 22h through the external electrodes 31, 32.

Thus, the laminated body 102 stretches, for example, in the laminating direction.

It is to be noted that in the stretchable film laminate 100, as shown in FIG. 5, the region 28 can be effectively used by forming the cut 25 so as to meet L₀>L₁ and D₀>D₁ when the vertical length of the stretchable film 21a is denoted by L₀, the vertical length of the cut 25 is denoted by L₁, the horizontal length of the stretchable film 21a is denoted by D₀, and the horizontal length of the cut 25 is denoted by D₁.

In addition, in the stretchable film laminate 100, the shapes and areas of the exposed parts of the main-surface electrodes 22c, 22e, 22g can be changed by changing the shapes of the cuts 25 to 27. Likewise, the shapes and areas of the exposed parts of the main-surface electrodes 22f, 22d, 22b can be changed by changing the shapes of the cuts 75 to 77.

In addition, the connections are achieved, but not limited thereto, with the external electrode 31 and the external electrode 32 in the first embodiment. External electrodes may be provided in multiple locations.

Next, a stretchable film laminate 200 according to a second embodiment of the present invention will be described below.

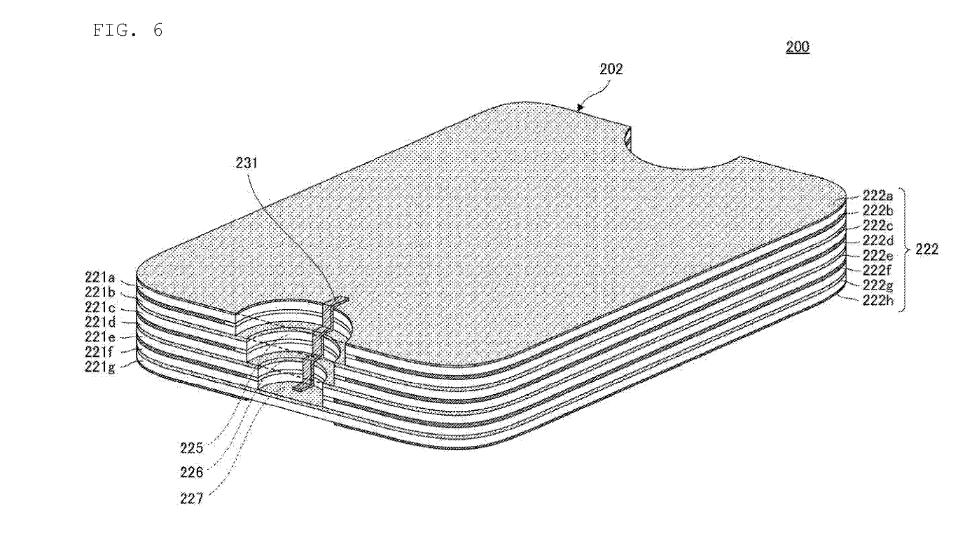

FIG. 6 is a perspective view of the appearance of the stretchable film laminate 200 according to the second embodiment of the present invention. The differences of the stretchable film laminate 200 from the stretchable film laminate 100 described previously are mainly the shapes of stretchable films 221a to 221g.

The stretchable films 221a to 221g have cuts 225 to 227 in curved shapes. The other configurations of the stretchable films 221a to 221g are the same as those of the stretchable films 21a to 21g, and the explanations thereof will be thus left out.

The main-surface electrode 222 of a laminated body 202 is composed of the plurality of main-surface electrodes 222a to 222h. The main-surface electrodes 222a to 222h have shape respectively in accordance with the stretchable films 221a to 221g.

More specifically, the main-surface electrodes 222a, 222c, 222e, 222g are connected to a first external electrode 231. The main-surface electrodes 222a, 222c, 222e, 222g are not connected to a second external electrode, not shown. In this regard, the first external electrode 231 and the second external electrode have the same material as the first external electrode 31.

In addition, the main-surface electrodes 222b 222d, 222f are located between the main-surface electrodes 222a and 222c, between the main-surface electrodes 222c and 222e, and between the main-surface electrodes 222e and 222g, respectively. The main-surface electrodes 222b, 222d, 222f, 222h are connected to the second external electrode, not shown. The main-surface electrodes 222b, 222d, 222f, 222h are not connected to the first external electrode 231.

The other main-surface electrodes 222a to 222h have the same configurations as the main-surface electrodes 22a to 22h, and the explanations thereof will be thus left out.

It is to be noted that the main-surface electrode 222a corresponds to the first main-surface electrode. The main-surface electrodes 222c, 222e correspond to the first main-surface electrode or the third main-surface electrode. The main-surface electrode 222g corresponds to the third main-surface electrode.

Further, the external electrode 231 is connected to a part of the main surface of the main-surface electrode 222a and parts of the main surfaces of the main-surface electrodes 222c, 222e, 222g exposed through the cuts 225 to 227.

In the foregoing configuration, in the stretchable film laminate 200, the first external electrode 231 can be connected to the main-surface electrodes 222a, 222c, 222e, 222g on the main-surface side where a large area can be ensured. Therefore, the connection area between the first external electrode 231 and the main-surface electrodes 222a, 222c, 222e, 222g is larger than the connection area of the piezoelectric speaker 90 in Patent Document 1.

Therefore, the stretchable film laminate 200 can improve the connection strength between the first external electrode 231 and the main-surface electrodes 222a, 222c, 222e, 222g, as with the stretchable film laminate 100.

In this regard, as shown in FIGS. 1 to 5, the stretchable films 21a to 21g are, because of the cuts 25 to 27, 75 to 77 with corners, likely to be ruptured from the corner parts in the stretching direction of the stretchable films 21a to 21g.

On the other hand, the stretchable film laminate 200 has the cuts 225 to 227 without any corner. Therefore, the stretchable film laminate 200 can prevent the stretchable films 221a to 221g from being ruptured.

Next, a stretchable film laminate 300 according to a third embodiment of the present invention will be described below.

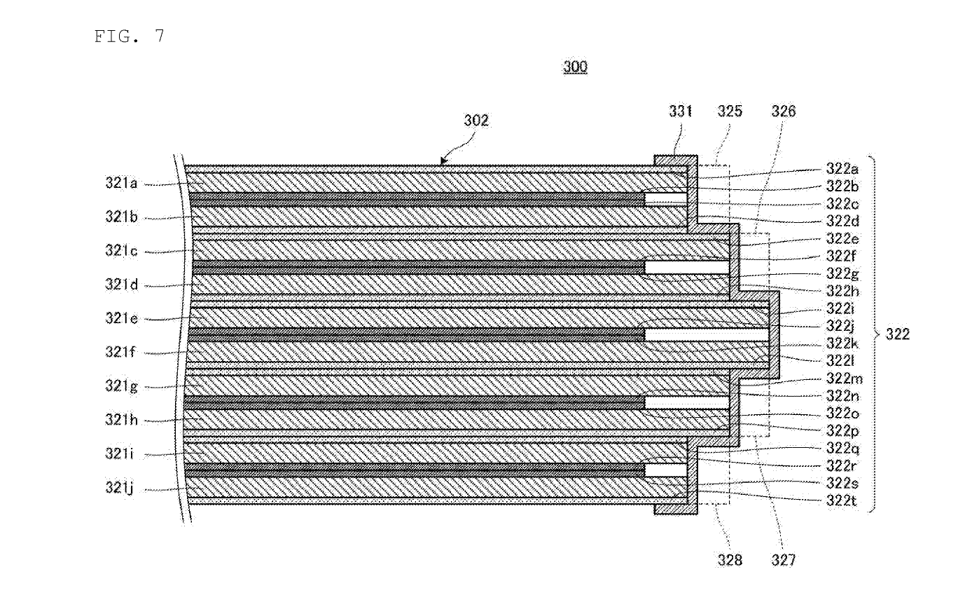

FIG. 7 is a cross-sectional view of a main part of a stretchable film laminate 300 according to a third embodiment of the present invention.

The differences of the stretchable film laminate 300 from the stretchable film laminate 100 described previously are mainly the end shapes of stretchable films 321a to 321j and the shape of a first external electrode 331.

The stretchable films 321a to 321d are provided with cuts 325, 326 such that the stretchable films 321a to 321f have respective ends in a stepwise manner. Main-surface electrodes 322e, 322i are partially exposed through the cuts 325, 326.

Furthermore, the stretchable films 321g to 321j are provided with cuts 327, 328 such that the stretchable films 321e to 321j have respective ends in a stepwise manner. Main-surface electrodes 322l, 322p are partially exposed through the cuts 327, 328.

The other stretchable films 321a to 321j have the same configurations as the stretchable films 21a to 21g, and the explanations thereof will be thus left out.

In addition, the main-surface electrode 322 of a laminated body 302 is composed of a plurality of main-surface electrodes 322a to 322t. The main-surface electrodes 322a to 322t have shape respectively in accordance with the stretchable films 321a to 321j.

The main-surface electrodes 322d, 322h, 322m, 322q are bonded to the main-surface electrodes 322e, 322i, 3221, 322p, respectively. Further, the main-surface electrodes 322a, 322d, 322e, 322h, 322i, 3221, 322m, 322p, 322q, 322t are connected to a first external electrode 331.

On the other hand, the main-surface electrodes 322a, 322d, 322e, 322h, 322i, 3221, 322m, 322p, 322q, 322t are not connected to a second external electrode, not shown. In this regard, the first external electrode 331 and the second external electrode have the same material as the first external electrode 31.

In addition, the main-surface electrodes 322b, 322c, 322f, 322g, 322j, 322k, 322n, 322o, 322r, 322s are located between the main-surface electrodes 322a and 322d, between the main-surface electrodes 322e and 322h, between the main-surface electrodes 322i and 322l, between the main-surface electrodes 322m and 322p, and between the main-surface electrodes 322q and 322t, respectively.

The main-surface electrodes 322b, 322c, 322f, 322g, 322j, 322k, 322n, 322o, 322r, 322s are connected to the second external electrode, not shown. The main-surface electrodes 322b, 322c, 322f, 322g, 322j, 322k, 322n, 322o, 322r, 322s are not connected to the first external electrode 331.

The other main-surface electrodes 322a to 322t have the same configurations as the main-surface electrodes 22a to 22h, and the explanations thereof will be thus left out.

It is to be noted that the main-surface electrodes 322a, 322t corresponds to the first main-surface electrodes. The main-surface electrodes 322e, 322p correspond to the first main-surface electrode or the third main-surface electrode. The main-surface electrode 322i, 3221 correspond to the third main-surface electrodes.

Further, the first external electrode 331 is connected to parts of the main surfaces of the main-surface electrodes 322a, 322t and parts of the main surfaces of the main-surface electrodes 322e, 322i, 3221, 322p exposed through the cuts 325 to 328.

In the foregoing configuration, in the stretchable film laminate 300, the first external electrode 331 can be connected to the main-surface electrodes 322a, 322e, 322i, 3221, 322p, 322t on the main-surface side where a large area can be ensured. Therefore, in the stretchable film laminate 300, the connection area between the external electrode 331 and the main-surface electrodes 322a, 322e, 322i, 3221, 322p, 322t is larger than the connection area of the piezoelectric speaker 90 in Patent Document 1.

Furthermore, in the stretchable film laminate 300, the first external electrode 331 sandwiches, from both sides, parts of the main surfaces of the main-surface electrodes 322a, 322e, 322i, 3221, 322p, 322t.

Therefore, the stretchable film laminate 300 can further improve the connection strength between the first external electrode 331 and the main-surface electrodes 322a, 322e, 322i, 3221, 322p, 322t.

Furthermore, as shown in FIG. 7, the first external electrode 331 sandwiches the parts from the both sides, thereby making it possible for the stretchable film laminate 300 to suppress warpage of the stretchable films 321a to 321j.

Next, a stretchable film laminate 400 according to a fourth embodiment of the present invention will be described below.

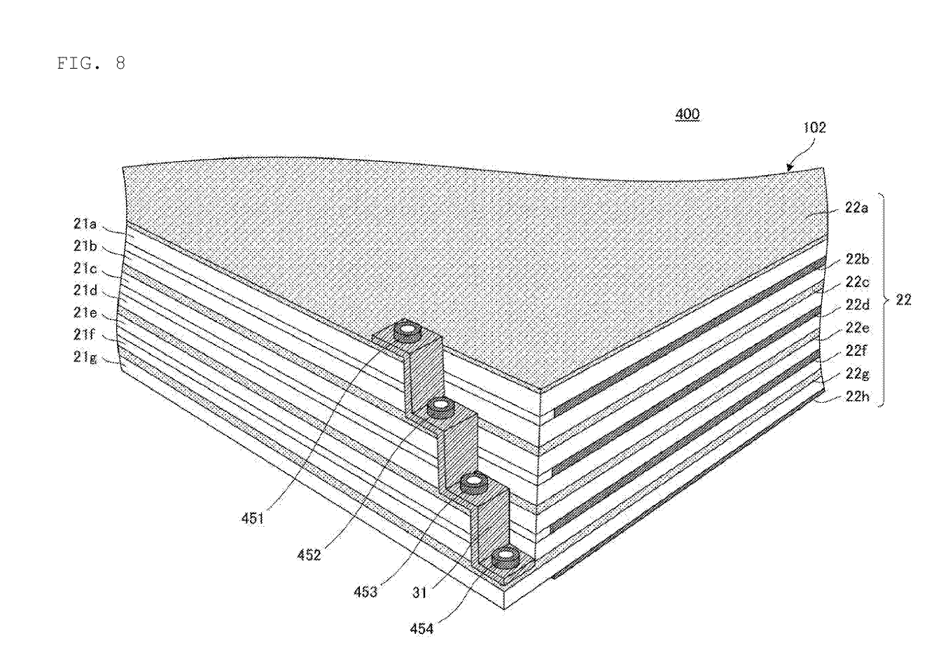

FIG. 8 is a perspective view of an interlayer connection part of the stretchable film laminate 400 according to the fourth embodiment of the present invention. The stretchable films 21a to 21g, main-surface electrode 22, and external electrode 31 provided for the stretchable film laminate 400 are the same as those of the stretchable film laminate 100 according to the first embodiment. The stretchable film laminate 400 is characterized by being fixed with the overlapped external electrode 31 and grommets 451 to 454, for each exposed part of the respective layers of the stretchable films 21a to 21g.

The stretchable film laminate 400 has the foregoing structure, and can thus firmly fix the external electrode 31 and the laminated body 102. In addition, the stretchable film laminate 400 can firmly press the contacts between the stretchable films 21a to 21g and the external electrode 31. This fixing method is an effective connecting method for resin films where it is not possible to use baked electrodes or thermosetting conductive adhesives because of low heat resistance. In addition, the stretchable film laminate 400 has connection made on the main-surface side, unlike structures with connection made at side surfaces as in the cited Document 1 mentioned previously, and thus can use connection methods such as grommets.

It is to be noted that while the exposed electrodes of the respective layers are each fixed to the external electrode with the grommets in the present embodiment, the two layers adjacent to each other may be fixed with one grommet. In addition, swaging terminals may be used instead of the grommets, and multiple layers may be swaged together.

In addition, in the respective embodiments described previously, the stretchable films can be composed of, for example, piezoelectric films, electrostrictive films, electret films, piezoelectric ceramics, composite films with piezoelectric particles dispersed in polymers, electroactive polymer films, or the like.

In this regard, the electroactive polymer film is a film that produce a stress by electrical drive, or a film that deforms and then produces displacement by electrical drive. Specifically, there are electrostrictive films, composite materials (materials of piezoelectric ceramics sealed with resin), electrically driven elastomers, or liquid crystal elastomers.

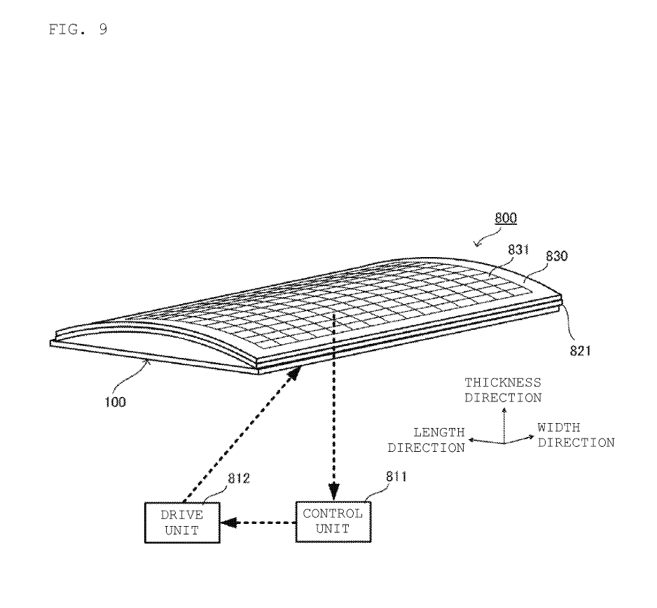

In addition, as described previously, the stretchable film laminates 100 to 400 have high connection reliability. Therefore, for example, as shown in FIG. 9, the stretchable film laminate 100 can be applied to an electronic device such as a keyboard 800. The keyboard 800 includes a control unit 811, a drive unit 812, a diaphragm 821, the stretchable film laminate 100, and a touch panel 830.

As shown in FIG. 9, the diaphragm 821, the stretchable film laminate 100, and the touch panel 830 are laminated in the thickness direction. The diaphragm 821 is bonded at both ends with an adhesive to both ends of the stretchable film laminate 100. Tension propagates to the diaphragm 821 from the stretchable film laminate 100, and the diaphragm 821 undergoes elastic deformation so as to undergo a deflection in the thickness direction.

The touch panel 830 is bonded with an adhesive to the top surface of the diaphragm 821. The touch panel 830 includes a plurality of touch sensors 831 exposed at top surface of the keyboard 800. The plurality of touch sensors 831 is disposed in positions corresponding to the key arrangement of the keyboard.

Each touch sensor 831 outputs, in response to the detection of a touch panel operation carried out by a user, the detection signal to the control unit 811. The control unit 811 outputs a control signal to the drive unit 812 when the detection signal is input from any of the touch sensors 831. The drive unit 812 applies a driving voltage to the stretchable film laminate 100 when a control signal is input from the control unit 811.

When an alternating-current driving voltage (driving signal) is applied from the leads bonded to the external electrodes 31, 32, the driving voltage is applied to the laminated body 102 from the main-surface electrodes 22a, 22c, 22e, 22g and the main-surface electrodes 22b, 22d, 22f, 22h through the external electrodes 31, 32. Thus, the stretchable film laminate 100 stretches, for example, in a planar direction. The diaphragm 821 vibrates with stretching of the stretchable film laminate 100.

Therefore, the keyboard 800 can provide a tactile feedback to users that carry out touch panel operations. It is to be noted that the keyboard 800 may include each of the stretchable film laminates 200 to 400, in place of the stretchable film laminate 100.

Finally, the descriptions of the respective embodiments should be considered by way of examples in all respects, but non-limiting. The scope of the present invention is specified by the claims, but not the embodiments described above. Furthermore, the scope of the present invention is intended to encompass all modifications within the spirit and scope equivalent to the claims.

### DESCRIPTION OF REFERENCE SYMBOLS

1: film layer
2: laminated body
5: first main-surface electrode
6: second main-surface electrode
9: positive electrode
10: negative electrode
11: diaphragm
12: adhesive layer
21a to 21g: stretchable film
22: main-surface electrode
26: region
31: first external electrode
32: second external electrode
90: piezoelectric speaker
100: stretchable film laminate
102: laminated body
200: stretchable film laminate
202: laminated body
221a to 221g: stretchable film
222: main-surface electrode
231: first external electrode
300: stretchable film laminate
302: laminated body
321a to 321j: stretchable film
322: main-surface electrode
331: first external electrode
400: stretchable film laminate
451 to 454: grommet
800: keyboard
811: control unit
812: drive unit
821: diaphragm
830: touch panel
831: touch sensor

1. A stretchable film laminate comprising:
a laminated body having:
a first main-surface electrode;
a first stretchable film having a first main surface thereof bonded to the first main-surface electrode and a second main surface opposed to the first main surface;
a second main-surface electrode bonded to the second main surface of the first stretchable film;
a second stretchable film with a third main surface bonded to the second main-surface electrode and a fourth main surface opposed to the third main surface; and
a third main-surface electrode bonded to the fourth main surface of the second stretchable film,
the first stretchable film and the second stretchable film having a first cut through which the third main-surface electrode is exposed; and
a first external electrode connected to the first main-surface electrode and the third main-surface electrode exposed through the first cut.

2. The stretchable film laminate according to claim 1, wherein the first external electrode is stepped.

3. The stretchable film laminate according to claim 1, wherein the first cut is curved.

4. The stretchable film laminate according to claim 1, wherein the laminated body further includes:
a third stretchable film with a fifth main surface bonded to the third main-surface electrode and a sixth main surface opposed to the fifth main surface; and
a fourth main-surface electrode bonded to the sixth main surface of the third stretchable film,
the second stretchable film and the third stretchable film having a second cut through which the second main-surface electrode is exposed, and
the laminate further comprises a second external electrode connected to the fourth main-surface electrode and the second main-surface electrode exposed through the second cut.

5. The stretchable film laminate according to claim 4, wherein one of the first external electrode and the second external electrode is stepped.

6. The stretchable film laminate according claim 4, wherein one of the first cut and the second cut is curved.

7. The stretchable film laminate according to claim 4, wherein the first through fourth main-surface electrodes and surfaces of any one of the first external electrode and the second external electrode in contact therewith include through holes, and the through holes are reinforced with swaged metal terminals or grommets.

8. The stretchable film laminate according to claim 1, wherein the first and second stretchable films are electrostrictive or piezoelectric stretchable films.

9. The stretchable film laminate according to claim 8, wherein the electrostrictive or piezoelectric stretchable films comprise a material selected from the group consisting of a vinylidene fluoride-ethylene trifluoride-chloroethene trifluoride terpolymer, a vinylidene fluoride-ethylene trifluoride copolymer, and a polyvinylidene fluoride that stretches more in a low electric field.

10. The stretchable film laminate according to claim 8, wherein the electrostrictive or piezoelectric stretchable films comprise a chiral polymer.

11. The stretchable film laminate according to claim 10, wherein the chiral polymer is a polylactic acid.

12. The stretchable film laminate according to claim 11, wherein the polylactic acid is an L-type polylactic acid.

13. The stretchable film laminate according to claim 4, wherein the first through third stretchable films are electrostrictive or piezoelectric stretchable films.

14. The stretchable film laminate according to claim 13, wherein the electrostrictive or piezoelectric stretchable films comprise a material selected from the group consisting of a vinylidene fluoride-ethylene trifluoride-chloroethene trifluoride terpolymer, a vinylidene fluoride-ethylene trifluoride copolymer, and a polyvinylidene fluoride that stretches more in a low electric field.

15. The stretchable film laminate according to claim 13, wherein the electrostrictive or piezoelectric stretchable films comprise a chiral polymer.

16. The stretchable film laminate according to claim 15, wherein the chiral polymer is a polylactic acid.

17. The stretchable film laminate according to claim 16, wherein the polylactic acid is an L-type polylactic acid.

18. An electronic device comprising:
the stretchable film laminate according to claim 1; and
a drive unit that applies a driving voltage to the stretchable film laminate.
